(19) United States
(12) Patent Application Publication
(10) Pub. No.: US 2025/0051924 A1
(43) Pub. Date: Feb. 13, 2025

(54) VAPOR DEPOSITION SYSTEMS AND METHODS, AND NANOMATERIALS FORMED BY VAPOR DEPOSITION

(71) Applicant: UNIVERSITY OF MARYLAND, COLLEGE PARK, College Park, MD (US)

(72) Inventors: Liangbing HU, Rockville, MD (US); Xizheng WANG, Irvine, CA (US)

(21) Appl. No.: 18/721,192

(22) PCT Filed: Dec. 22, 2022
(86) PCT No.: PCT/US2022/053771

§ 371 Date: Jun. 18, 2024

Related U.S. Application Data
(60) Provisional application No. 63/265,859, filed on Dec. 22, 2021.

(51) Int. Cl. C23C 16/52; B82Y 30/00; C23C 16/06; C23C 16/50; C23C 16/54

(52) U.S. Cl. CPC C23C 16/52; B82Y 30/00; C23C 16/06; C23C 16/50; C23C 16/54

(57) ABSTRACT

A vapor deposition system can have a support member, a baffle member, and a deposition substrate. The support member can hold a batch of solid-state precursors. The baffle member can be disposed over and spaced from the support member to define a confined heating volume with at least one exit window. The deposition substrate can be disposed over and spaced from the baffle member. The batch of solid-state precursors can be subjected to a temperature greater than 2200, so as to convert at least some of the solid-state precursors into a vapor that exits the confined heating volume via the at least one exit window, flows around the baffle member, and solidifies on the deposition substrate surface. In some embodiments, the baffle member can comprise a heating element. Alternatively or additionally, the vapor deposition system can have a separate heating system.

### CROSS-REFERENCE TO RELATED APPLICATION

The present application claims the benefit of U.S. Provisional Application No. 63/265,859, filed Dec. 22, 2021, entitled “Metal Nanodisks via High Temperature Vapor to Crystal Deposition,” which is incorporated by reference herein in its entirety.

### FIELD

The present disclosure relates generally to material deposition, and more particularly, to vapor deposition systems and methods, and nanomaterials formed by vapor deposition.

### BACKGROUND

Fabrication of single-phase, uniformly-mixed, multi-elemental nanomaterials generally requires complete bond dissociation of the reaction precursors at a high temperature followed by rapid thermal quenching to prevent phase separation of the final product. While such atomic mixing has been demonstrated in various non-equilibrium, solid-solution-based methods, it can be difficult to control the composition and structure of the resulting products. Moreover, such products are typically limited to spherical nanoparticles.

In vapor-phase synthesis techniques, such as chemical vapor deposition (CVD) or flame synthesis, reaction precursors are vaporized to promote mixing of different atomic species in the vapor phase followed by rapid temperature quenching to promote nucleation and growth into desired single-phase nanostructures. However, vapor-phase synthesis requires significant breakage and formation of atomic bonds, which can be challenging to achieve without producing unwanted side-products or requiring catalysts. In addition, such catalysts can be expensive and difficult to remove. Moreover, since the flame in flame synthesis is usually produced by burning a flammable gas (e.g., methane) in air, the synthesis temperature is limited to 2200 K. The air atmosphere employed in flame synthesis may also not be suitable for the production of metallic particles that can be easily oxidized. Accordingly, the nanomaterials that can be successfully synthesized by conventional vapor-phase synthesis techniques are limited.

Embodiments of the disclosed subject matter may address one or more of the above-noted problems and disadvantages, among other things.

### SUMMARY

Embodiments of the disclosed subject matter provide a novel vapor deposition technique, which can be used to form nanomaterials and/or coatings. In some embodiments, solid-state precursors can be subjected to a high temperature (e.g., ≥2200 K), which can rapidly vaporize and decompose the precursors into high-temperature reactive vapor (e.g., atomic species). A baffle member can be disposed between a deposition substrate and the precursors to define a confined heating volume with exit windows (e.g., open faces defined by vertical gaps between the baffle member and a support holding the precursors). In some embodiments, the baffle member can comprise a heating element that subjects the precursors to the high temperature. The vapor generated within the confined volume can expand outward and exit the confined heating volume via the exits windows. The high-temperature vapor can then be carried upwards by buoyancy forces (e.g., convection) and can be incident on a facing surface of a lower-temperature (e.g., <1000 K) noncatalytic substrate. Due to fluid dynamics (e.g., similar to a Coanda effect), the provision of the baffle member between the substrate and the precursors can cause the vapor to adopt a spatially-confined flow toward the deposition substrate without requiring a separate physically-confining structure between the baffle member and the substrate. Thus, the vapor can deposit, nucleate, and grow into highly-uniform and pure multi-element products on the substrate, with excellent compositional and structural control.

In one or more embodiments, a method can comprise providing a baffle member, a deposition substrate, a support member, and a first batch of solid-state precursors on the support member. The baffle member can be disposed over and spaced from the support member by a first distance along a first direction. The baffle and support members can be constructed and arranged so as to define a confined heating volume with at least one exit window. The deposition substrate can be disposed over and spaced from the baffle member by a second distance along the first direction. The method can further comprise subjecting the first batch of solid-state precursors to a first temperature greater than 2200 K, so as to convert at least some of the solid-state precursors into a vapor that exits the confined heating volume via the at least one exit window. During at least part of the subjecting of (b), the deposition substrate can be at a second temperature less than the first temperature, and the exiting vapor can flow around the baffle member into contact with a surface of the deposition substrate such that the vapor solidifies on said deposition substrate surface.

In one or more embodiments, a system can comprise a support member, a baffle member, a deposition substrate, and a controller. The support member can be constructed to hold one or more batches of solid-state precursors thereon. The baffle member can be disposed over and spaced from the support member by a first distance along a first direction. The baffle and support members can be constructed and arranged to define a confined heating volume with at least one exit window. The deposition substrate can be disposed over and spaced from the baffle member by a second distance along the first direction. The controller can comprise one or more processors and one or more computer readable storage media. The baffle member can comprise a heating element. The one or more computer readable storage media can store instructions that, when executed by the one or more processors, cause the controller to control the heating element to subject a batch of solid-state precursors within the confined heating volume to a first temperature greater than 2200 K, so as to convert at least some of the solid-state precursors into a vapor that exits the confined heating volume via the at least one exit window, flows around the baffle member into contact with a surface of the deposition substrate, and solidifies on said deposition substrate surface.

In one or more embodiments, a system can comprise a support member, a baffle member, a deposition substrate, a heating system, and a controller. The support member can be constructed to hold one or more batches of solid-state precursors thereon. The baffle member can be disposed over and spaced from the support member by a first distance along a first direction. The baffle and support members can be constructed and arranged to define a confined heating volume with at least one exit window. The deposition substrate can be disposed over and spaced from the baffle member by a second distance along the first direction. The controller can be operatively coupled to the heating system. The controller can comprise one or more processors and one or more computer readable storage media storing instructions that, when executed by the one or more processors, cause the controller to control the heating system to subject a batch of solid-state precursors within the confined heating volume to a first temperature greater than 2200 K, so as to convert at least some of the solid-state precursors into a vapor that exits the confined heating volume via the at least one exit window, flows around the baffle member into contact with a surface of the deposition substrate, and solidifies on said deposition substrate surface.

Any of the various innovations of this disclosure can be used in combination or separately. This summary is provided to introduce a selection of concepts in a simplified form that is further described below in the detailed description. This summary is not intended to identify key features or essential features of the claimed subject matter, nor is it intended to be used to limit the scope of the claimed subject matter. The foregoing and other objects, features, and advantages of the disclosed technology will become more apparent from the following detailed description, which proceeds with reference to the accompanying figures.

### BRIEF DESCRIPTION OF THE DRAWINGS

Embodiments will hereinafter be described with reference to the accompanying drawings, which have not necessarily been drawn to scale. Where applicable, some elements may be simplified or otherwise not illustrated in order to assist in the illustration and description of underlying features. Throughout the figures, like reference numerals denote like elements.

FIG. 1A is a simplified schematic diagram of a vapor deposition system, according to one or more embodiments of the disclosed subject matter.

FIG. 1B is a graph illustrating an exemplary temperature profile employed in a vapor deposition system, according to one or more embodiments of the disclosed subject matter.

FIGS. 2A-2B are a simplified schematic diagram and digital image, respectively, illustrating operation of a vapor deposition system, according to one or more embodiments of the disclosed subject matter.

FIG. 2C is a digital image illustrating operation of a vapor deposition system without baffle member, according to one or more embodiments of the disclosed subject matter.

FIG. 3A is a simplified schematic diagram illustrating a vapor deposition system with active cooling of the deposition substrate, according to one or more embodiments of the disclosed subject matter.

FIG. 3B is a simplified schematic diagram illustrating a vapor deposition system employing an array of heating element portions, according to one or more embodiments of the disclosed subject matter.

FIG. 3C is a simplified schematic diagram illustrating a vapor deposition system with non-heating baffle member, according to one or more embodiments of the disclosed subject matter.

FIG. 3D is a simplified schematic diagram illustrating a vapor deposition system employing a separate heating system, according to one or more embodiments of the disclosed subject matter.

FIG. 4A is a simplified schematic diagram of a continuous vapor deposition system with roll-to-roll deposition substrate, according to one or more embodiments of the disclosed subject matter.

FIG. 4B is a simplified schematic diagram of a continuous vapor deposition system with static deposition substrate, according to one or more embodiments of the disclosed subject matter.

FIGS. 4C-4D are a simplified schematic diagram and digital image, respectively, illustrating operation of a continuous vapor deposition system, according to one or more embodiments of the disclosed subject matter.

FIG. 5 depicts a generalized example of a computing environment in which the disclosed technologies may be implemented.

FIG. 6A is a scanning electron microscopy (SEM) image of vapor-deposited Mo₄₅Co₂₅Fe₁₅Ni₁₅Oₓ nanodisks.

FIG. 6B shows high-angle annular darkfield scanning transmission electron microscopy (HAADF-STEM) and high-angle annular darkfield energy dispersive X-ray spectroscopy (HAADF-EDS) images of vapor-deposited Mo₄₅Co₂₅Fe₁₅Ni₁₅Oₓ nanodisks.

FIGS. 6C-6D show HAADF-STEM and HAADF-EDS images of vapor-deposited Mo₄₅Co₂₅Fe₁₀Ni₁₀Mn₁₀Oₓ nanodisks.

FIG. 6E shows a high-resolution HAADF-SE™ image of a vapor-deposited Mo₄₅Co₂₅Fe₁₀Ni₁₀Mn₁₀Oₓ nanodisk, with selected area electron diffraction (SAED) shown in the inset.

FIG. 6F shows a simulated electron diffraction pattern of Co₂Mo₃O₈ featuring an A₂B₃O₈ hexagonal structure (P6_{3mc} space group).

FIG. 7A shows scanning transmission electron microscopy (STEM) and STEM energy dispersive X-ray spectroscopy (STEM-EDS) images of a vapor-deposited ZrO₂ film.

FIG. 7B shows STEM and STEM-EDS images of vapor-deposited polyhedron FeCoNiCuPd alloy nanoparticles.

FIG. 7C shows STEM and STEM-EDS images of vapor-deposited polyhedron FeCoNiS nanoparticles.

FIG. 8A shows measured temperature profiles for a Joule heating element and deposition substrate during cycled heating operation.

FIG. 8B is a digital image of operation of a vapor deposition system during cycled heating.

FIG. 8C is an SEM image of Mo₄₅Co₂₅Fe₁₀Ni₁₀Mn₁₀Oₓ nanodisks formed on the deposition substrate after seven rounds (e.g., ˜49 s) of cycled heating.

FIG. 8D shows measured temperature profiles for a Joule heating element and deposition substrate during continuous heating operation.

FIG. 8E is a digital image of operation of a vapor deposition system during continuous heating.

FIG. 8F is an SEM image of Mo₄₅Co₂₅Fe₁₀Ni₁₀Mn₁₀Oₓ nanodisks formed on the deposition substrate after continuous heating (e.g., ˜15 s).

### DETAILED DESCRIPTION

### General Considerations

For purposes of this description, certain aspects, advantages, and novel features of the embodiments of this disclosure are described herein. The disclosed methods and systems should not be construed as being limiting in any way. Instead, the present disclosure is directed toward all novel and nonobvious features and aspects of the various disclosed embodiments, alone and in various combinations and sub-combinations with one another. The methods and systems are not limited to any specific aspect or feature or combination thereof, nor do the disclosed embodiments require that any one or more specific advantages be present, or problems be solved. The technologies from any embodiment or example can be combined with the technologies described in any one or more of the other embodiments or examples. In view of the many possible embodiments to which the principles of the disclosed technology may be applied, it should be recognized that the illustrated embodiments are exemplary only and should not be taken as limiting the scope of the disclosed technology.

Although the operations of some of the disclosed methods are described in a particular, sequential order for convenient presentation, it should be understood that this manner of description encompasses rearrangement, unless a particular ordering is required by specific language set forth below. For example, operations described sequentially may in some cases be rearranged or performed concurrently. Moreover, for the sake of simplicity, the attached figures may not show the various ways in which the disclosed methods can be used in conjunction with other methods. Additionally, the description sometimes uses terms like “provide” or “achieve” to describe the disclosed methods. These terms are high-level abstractions of the actual operations that are performed. The actual operations that correspond to these terms may vary depending on the particular implementation and are readily discernible by one skilled in the art.

The disclosure of numerical ranges should be understood as referring to each discrete point within the range, inclusive of endpoints, unless otherwise noted. Unless otherwise indicated, all numbers expressing quantities of components, molecular weights, percentages, temperatures, times, and so forth, as used in the specification or claims are to be understood as being modified by the term “about.” Accordingly, unless otherwise implicitly or explicitly indicated, or unless the context is properly understood by a person skilled in the art to have a more definitive construction, the numerical parameters set forth are approximations that may depend on the desired properties sought and/or limits of detection under standard test conditions/methods, as known to those skilled in the art. When directly and explicitly distinguishing embodiments from discussed prior art, the embodiment numbers are not approximates unless the word “about” is recited. Whenever “substantially.” “approximately.” “about,” or similar language is explicitly used in combination with a specific value, variations up to and including 10% of that value are intended, unless explicitly stated otherwise.

Directions and other relative references may be used to facilitate discussion of the drawings and principles herein but are not intended to be limiting. For example, certain terms may be used such as “inner,” “outer,” “upper,” “lower.” “top,” “bottom,” “interior,” “exterior.” “left,” right.” “front,” “back,” “rear,” and the like. Such terms are used, where applicable, to provide some clarity of description when dealing with relative relationships, particularly with respect to the illustrated embodiments. Such terms are not, however, intended to imply absolute relationships, positions, and/or orientations. For example, with respect to an object, an “upper” part can become a “lower” part simply by turning the object over. Nevertheless, it is still the same part, and the object remains the same.

As used herein, “comprising” means “including.” and the singular forms “a” or “an” or “the” include plural references unless the context clearly dictates otherwise. The term “or” refers to a single element of stated alternative elements or a combination of two or more elements unless the context clearly indicates otherwise.

Although there are alternatives for various components, parameters, operating conditions, etc. set forth herein, that does not mean that those alternatives are necessarily equivalent and/or perform equally well. Nor does it mean that the alternatives are listed in a preferred order, unless stated otherwise. Unless stated otherwise, any of the groups defined below can be substituted or unsubstituted.

Unless explained otherwise, all technical and scientific terms used herein have the same meaning as commonly understood to one skilled in the art to which this disclosure belongs. Although methods and materials similar or equivalent to those described herein can be used in the practice or testing of the present disclosure, suitable methods and materials are described below. The materials, methods, and examples are illustrative only and not intended to be limiting. Features of the presently disclosed subject matter will be apparent from the following detailed description and the appended claims.

### Overview of Terms

The following is provided to facilitate the description of various aspects of the disclosed subject matter and to guide those skilled in the art in the practice of the disclosed subject matter.

Vapor Generating Temperature: A peak or maximum temperature at a surface of one or more heating elements when energized (e.g., by application of a current pulse) and/or at a surface of a material being heated. In some embodiments, the vapor generating temperature is at least about 2200 K, for example, in a range of about 2500 K to about 3000 K, inclusive. In some embodiments, a temperature at a material being heated (e.g., precursors on a substrate) can match or substantially match (e.g., within 10%) the temperature of the heating element.

Particle size: A maximum cross-sectional dimension (e.g., diameter) of one or more particles. In some embodiments, an identified particle size represents an average particle size for all particles (e.g., an average of the maximum cross-sectional dimensions). In some embodiments, the particle size can be measured according to one or more known standards, such as, but not limited to, ASTM B214-16 entitled “Standard Test Method for Sieve Analysis of Metal Powders,” ASTM B330-20 entitled “Standard Test Methods for Estimating Average Particle Size of Metal Powders and Related Compounds Using Air Permeability,” ASTM B822-20 entitled “Standard Test Method for Particle Size Distribution of Metal Powders and Related Compounds by Light Scattering.” and ASTM B922-20 entitled “Standard Test Method for Metal Powder Specific Surface Area by Physical Adsorption,” all of which are incorporated by reference herein.

Nanomaterial: An engineered particle formed of one or more elements and having a maximum cross-sectional dimension (e.g., diameter when the particle is spherical) less than or equal to about 1 μm, for example, about 500 nm or less. In some embodiments, the nanomaterial has a maximum cross-sectional dimension of less than or equal to about 300 nm, for example, in a range of 100-300 nm, inclusive. In some embodiments, the nanomaterial is formed of at least two (2) elements, for example, three (3) or more elements.

### Introduction

Disclosed herein is a catalyst-free vapor deposition technique that can be used to fabricate, for example, single-phase, multi-element nanomaterials and/or thin films. In embodiments, the vapor deposition technique employs a unique reactor design with a semi-confined heating zone defined at least in part by a baffle member arranged over and spaced from the solid-state precursors undergoing vaporization. In some embodiments, the baffle member can comprise a heating element (e.g., a Joule heating element) that can rapidly produce ultrahigh temperatures (e.g., vapor generating temperature≥2200 K, such as ˜ 3000 K). Alternatively, in some embodiments, a heating system separate from the baffle member is employed to subject the precursors to the ultrahigh temperatures.

The ultrahigh temperature heating can rapidly decompose the precursors into a high-flux, ultrahigh temperature of atomic species that expands to escape from the semi-confined heating zone and then flows upward and around the baffle member in a spatially-confined and stable manner. In some embodiments, the heating is such that the solid precursors directly transition to the vapor phase (e.g., without turning to liquid first, or without a perceptible liquid phase transition). The atomic species in the vapor flow mix and form intermediates that ultimately nucleate, grow, and crystalize into solid products (e.g., thin film or nanomaterials) on a lower temperature deposition substrate disposed above the baffle member. In this manner, the ultrahigh temperature vapor can be used as a highly non-equilibrium vapor-to-solid deposition platform, in which the precursor decomposition, atomic vapor heating, cooling, and deposition process can be precisely controlled (e.g., by tuning the heating with a high temporal resolution and spatial uniformity and/or by changing the distance between the deposition substrate and the baffle member and/or heating element).

In some embodiments, the deposition process can be substantially continuous. For example, in some embodiments, the heating element may be periodically energized, for example, to avoid raising an average temperature of the deposition substrate above a predetermined threshold (e.g., average temperature≤600 K). Nevertheless, the deposition may continue on the substrate even though the heating element is temporarily off, and thus the process may be considered continuous. Alternatively or additionally, in some embodiments, the heating element may be continuously energized, and the temperature of the deposition substrate maintained by cooling (e.g., passive or active cooling techniques), by moving a different portion of the deposition substrate into position for deposition (e.g., in a roll-to-roll configuration), or any combination of the foregoing.

Embodiments of the disclosed subject matter can employ ultrahigh temperatures (e.g., 2500-3000 K) in order to enable the solid-state precursors to fully decompose into highly reactive atomic species. In some embodiments, a continuous, stable, and high-velocity vapor flow can be generated by the ultrahigh temperatures, which can enable the production of single-crystal multi-elemental nanomaterials under non-equilibrium conditions via rapid heating and quenching. In some embodiments, the vapor deposition technique can achieve uniform mixing of different (even immiscible) elements for the synthesis of a broad materials space (e.g., alloys, oxides, sulfides, etc.). In some embodiments, various parameters (e.g., substrate spacing, substrate temperature, and/or heating cycle duration) can be controlled to tune size and/or yield of the deposited nanomaterials or films.

This non-equilibrium vaporization process can also synthesize a wide range of nanomaterials, including multi-elemental alloy, oxide, and sulfide nanoparticles (e.g., featuring uniformly-mixed, immiscible elements), as well as two-dimensional thin film coatings (e.g., having a thickness≤10 μm). Embodiments of the disclosed subject matter can employ uses electrically-powered heating (e.g., Joule heating) to vaporize the solid precursors without the need of catalyst, fuel, or oxidizer, ensuring a high compositional and structural control. In contrast, chemical vapor deposition (CVD) typically requires a catalyst, while flame synthesis typically requires fuel and O₂ as an oxidizer, which can make it more difficult to synthesize non-oxide materials as well as releasing CO₂. Moreover, in some embodiments, the ultrahigh operating temperature of the disclosed vapor deposition technique can enable the vaporization of most of the solid-state precursors, which can eliminate the need for solvent or expensive, high vapor-pressure reactants, and thereby simplify the reaction process and expand potential materials space.

### Vapor Deposition Systems

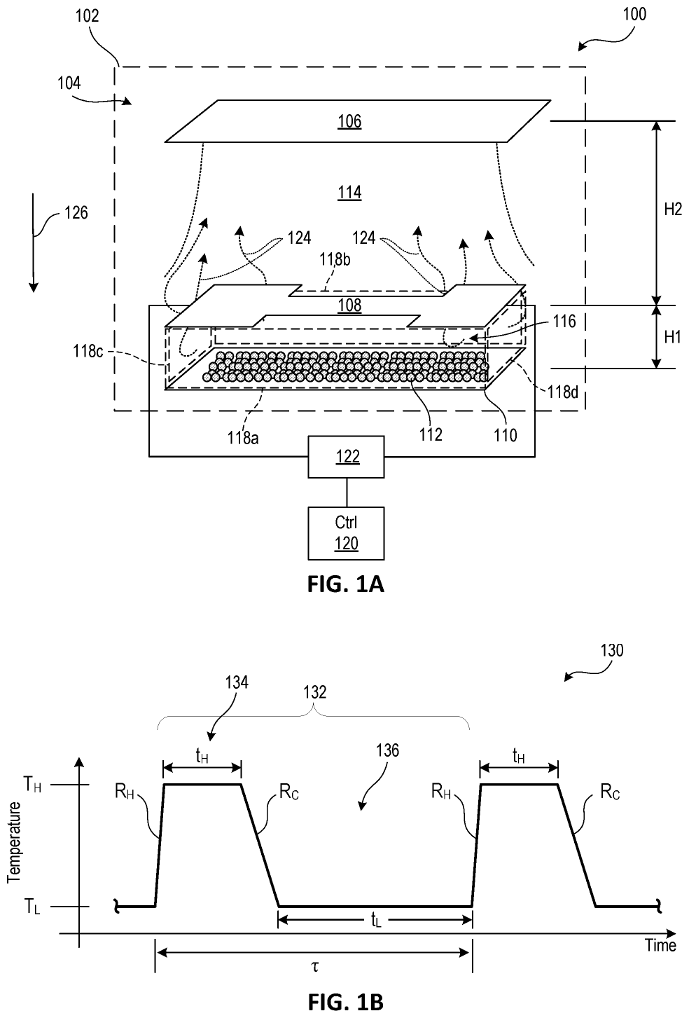

FIG. 1A illustrates a vapor deposition system 100 that can be used to fabricate nanomaterials and/or a thin film coating on a deposition substrate 106. The system 100 can include a support member 110 and a baffle member 108. The system 100 can also have a reactor 102 that defines an internal volume 104, in which the support member 110, the baffle member 108, and the deposition substrate 106 are disposed. In some embodiments, the internal volume 104 of the reactor 102 can be filled with an inert gas (e.g., nitrogen, argon, helium, neon, krypton, xenon, and/or radon), for example, at atmospheric pressure. Alternatively, in some embodiments, the internal volume 104 of the reactor 102 can be under vacuum (e.g., less than atmospheric pressure). The support member 110 can hold one or more solid-state precursors 112 (e.g., metal salts) that when subjected to the ultrahigh temperature heating (e.g., ≥2200 K) decomposes into vapor 124. In some embodiments, the deposition substrate 106, the baffle member 108, and/or the support member 110 can be formed of a material capable of withstanding such ultrahigh temperatures, for example, a refractory material such as carbon (e.g., carbon paper, carbon felt, carbon nanofibers, graphite plate etc.).

The baffle member 108 and the support member 110 can be spaced from each other by a first distance H1 along a direction 126 parallel to gravity, so as to define a confined heating volume 116 with the precursors 112 therein. The deposition substrate 106 and the baffle member 108 can be spaced from each other by a second distance H2 along the direction 126 parallel to gravity, so as to define a reaction region 114. In some embodiments, the second distance H2 is greater than the first distance H1. For example, the second distance H2 may be at least 10 times the first distance. In some embodiments, the first distance H1 may be less than or equal to 10 mm, for example, in a range of 100 μm to 2 mm, inclusive. Alternatively or additionally, the second distance H2 may be less than or equal to 10 cm, for example, in a range of 2 cm to 6 cm, inclusive.

The confined heating volume 116 may be open at one or more horizontal ends thereof so as to define vapor exit windows 118a-118d, for example, formed by the vertically-oriented gap between the baffle member 108 and the support member 110. The generated vapor 124 can thus exit the confined heating volume 116 via the exit windows 118a-118d and convect upward through the reaction region 114 driven by buoyancy forces. In some embodiments, the disposition of the baffle member 108 between the precursors 112 and the deposition substrate 106 causes the resultant vapor 124 to adopt a spatially-confined flow toward the deposition substrate 106, for example, without requiring a separate structural feature within reaction region to physically confine the vapor flow.

In some embodiments, at least a portion of the baffle member 108 can be a Joule heating element. For example, the baffle member 108 can be connected to an electrical power supply 122 that provides an appropriate current and/or voltage to the Joule heating element to generate the desired vapor generation temperature. In some embodiments, the baffle member 108 can be formed of a porous conductive material, for example, a carbon paper or felt. In some embodiments, the baffle member 108 can be shaped with an intermediate narrowed portion (e.g., dogbone-shaped), such that the narrowed portion has a higher electrical resistance than the surrounding portions of the baffle member 108 and thus serves as the Joule heating element. Although similarly illustrated in the example of FIG. 1A, in some embodiments, a planar area (e.g., in the horizontal plane perpendicular to the direction 126) of the baffle member 108 can be less than that of the deposition substrate 106. In some embodiments, a controller 120 can be operatively coupled to the power supply 122, for example, to control operation of the heating element to effect the desired vapor deposition. Although shown separately in the illustrated example, in some embodiments, the controller 120 and the power supply 122 can be integrated together, for example, with the controller 120 directly providing the current/voltage to the heating element to effect the desired heating.

In some embodiment, the Joule heating can be similar to any of the systems or configurations disclosed in U.S. Publication No. 2018/0369771, published Dec. 27, 2018 and entitled “Nanoparticles and systems and methods for synthesizing nanoparticles through thermal shock,” U.S. Publication No. 2019/0161840, published May 30, 2019 and entitled “Thermal shock synthesis of multielement nanoparticles,” International Publication No. WO 2020/236767, published Nov. 26, 2020 and entitled “High temperature sintering systems and methods,” International Publication No. WO 2020/252435, published Dec. 17, 2020 and entitled “Systems and methods for high temperature synthesis of single atom dispersions and multi-atom dispersions,” and International Publication No. WO 2022/204494, published Sep. 29, 2022 and entitled “High temperature sintering furnace systems and methods,” each of which is incorporated herein by reference.

For example, in some embodiments, the baffle member 108 can be suspended approximately 1 mm above the solid-state precursors 112, and at least a portion of the baffle member 108 can serve as a Joule heating element. The precursors 112 can thus be semi-confined in the volume 116 formed between the baffle member 108 and the support member 110, with the surrounding sides 118a-118d remaining open. By appropriate control of the current from the power supply 122 to the baffle member 108, the process temperature and heating duration can be finely tuned with high temporal resolution (e.g., ˜ 1 ms). For example, the Joule heating can generate ultrahigh temperatures (e.g., 2500-300 K) via a fast heating rate (e.g., 10+K/s) and high spatial uniformity.

In some embodiments, the fast heating rate and the close proximity of the heating element can cause the solid-state precursors 112 (e.g., metal salts) to rapidly decompose and transition to a high-temperature vapor state without an intermediate liquid phase. In some embodiments, the transition of the precursors 112 to products (e.g., nanomaterials or thin film coating formed on the deposition substrate 106) can be endothermic, with the ultrahigh temperature generated by the Joule heating element of the baffle member 108 providing sufficient activation energy for the dissociation of the chemical bonds in the precursors. As a result, in some embodiments, the precursors can decompose into atomic species in the vapor phase. The resulting high flux vapor 124 can expand outward from the exit windows 118a-118d and flows directly above the baffle member 108 via a buoyancy-driven flow.

As the vapor 124 convects upwards through the reaction region 114 away from the baffle member 108, the temperature can drop, which can induce recombination of the atomic species into molecular intermediates. In some embodiments, the reformation of chemical bonds between the atomic species can release heat, which can yield a local temperature plateau of the vapor phase within the reaction region. But at the cooler substrate 106, the atomic and molecular intermediate species of the vapor 124 transition back into the solid state, nucleating and growing into the desired nanomaterial products or a thin film coating, for example, on the surface of the deposition substrate 106 facing the baffle member 108. In some embodiments, the mixing of the atomic species within the vapor phase and the subsequent cooling at the deposition substrate 106 can yield products with uniform elemental mixing without phase segregation.

In some embodiments, at least the second distance H2 can be selected to achieve a desired particle size for nanomaterials deposited on the substrate 106, with larger values of H2 resulting in larger particles and/or size distribution and smaller values of H2 resulting in smaller particles and/or size distribution. In some embodiments, when the second distance H2 is too great (e.g., >6 cm), excess growth of particles can result in the vapor phase, and the resulting particles may be too heavy to be carried by the buoyancy effects to the substrate, leading to suboptimal yield. Alternatively, in some embodiments, when the second distance H2 is too small (e.g., <2 cm), the deposition substrate 106 may be excessively heated (e.g., having an average temperature>1000 K), which can make it difficult for vapor phase species to nucleate on the substrate and can generate competing flow effects due to hot gases around the substrate (which can limit contact of the vapor with the substrate).

Alternatively or additionally, in some embodiments, the subjecting to the vapor generating temperature can be periodic or cyclical, so as to maintain an average temperature of the deposition substrate 106 below a predetermined threshold. For example, FIG. 1B shows an exemplary cyclic heating profile 130 for the Joule heating element in the vapor deposition system to avoid overheating the deposition substrate. In some embodiments, the heating profile 130 can provide a rapid transition to and/or from the vapor generating temperature TH, for example, from/to a low temperature T_{L}, such as room temperature (e.g. 20-25° C.) or an elevated temperature (e.g., 1000-1500 K). The rapid heating rate coupled with the ultrahigh vapor generating temperature can ensure a rapid initial evaporation of the precursors in order to bypass the liquid phase (e.g., without discernible melting). Otherwise, the precursors may be heated too slowly and melt into the liquid phase first, which can make it difficult to confine the liquid precursors and form a stable vapor.

For example, each heating cycle 132 (e.g., having a period τ≤20 s, for example, ˜7 s) can have (i) a rapid heating R_{H} (e.g., ≥10² K/s, such as 10²-10⁵ K/s, inclusive) where the Joule heating element is energized, (ii) a heating period 134 having a short duration, t_{H} (e.g., 5 s or less, such as in a range of 100 ms to 2 s, for example, ˜2 s), where the current to the Joule heating element is maintained to yield the vapor generating temperature T_{H} (e.g., ≥2200 K, for example, in a range of 2500-3000 K), (iii) a rapid cooling ramp R_{C} (e.g., ≥102 K/s, such as 10²-10³ K/s, inclusive) after the Joule heating element is de-energized, and (iv) a no-heating period 136 having a short duration, t_{L} (e.g., 10 s or less, for example, ˜ 5s), where no current is supplied to the Joule heating element. The provision of the no-heating period 136 can thus maintain the deposition substrate 106 at a sufficiently low average temperature (e.g., <1000 K, such as ≤˜600K) for effective vapor deposition by allowing the deposition substrate 106 to naturally cool between successive heating periods 134. Alternatively or additionally, in some embodiments, the deposition substrate 106 can be cooled during the heating period 134 and/or during the no-heating period 136 (or the no-heating period 136 may be omitted in favor of substantially continuous heating), for example, by using one or more passive cooling features (e.g., heat sinks thermally coupled to the substrate, etc.), one or more active cooling features (e.g., fluid flow directed at the substrate, fluid flow through a heat sink thermally coupled thereto, etc.), or any combination thereof.

In some embodiments, by employing ultrahigh temperatures to generate the vapor and by mixing with other more easily evaporated metals (e.g., Fe, Co, Ni, Mn), even low vapor-pressure elements (e.g., Mo) can be incorporated into the gas phase to form a stable vapor. Indeed, when provided in a single species, Mo can barely evaporate due to its significantly lower vapor pressure. However, when mixed with a higher ratio of easily evaporated metallic elements, the Mo can be effectively vaporized, which may be due to interactions of Mo with the more volatile species that help promote Mo into the vapor phase.

Although the above discussion is directed to providing precursors with different elemental compositions together and mixing within the vapor to form multi-element products, embodiments of the disclosed subject matter are not limited thereto. Rather, the vapor deposition system disclosed herein can be readily adapted to other vapor-synthesis techniques, such as but not limited to atomic layer deposition. For example, the configuration of FIG. 1A can be used with precursors 112 for a single element (e.g., a single metal salt). The resulting vapor can deposit on and/or react with the deposition substrate 106, for example, to yield a first solid element or sublayer thereon. Additional or different precursors 112 (e.g., a different single element) can subsequently be introduced to the support member 110, and the process repeated to yield a second solid element or sublayer on the first solid element or layer. The process can be repeated to form a desired single element or multi-element layer on the deposition substrate 106.

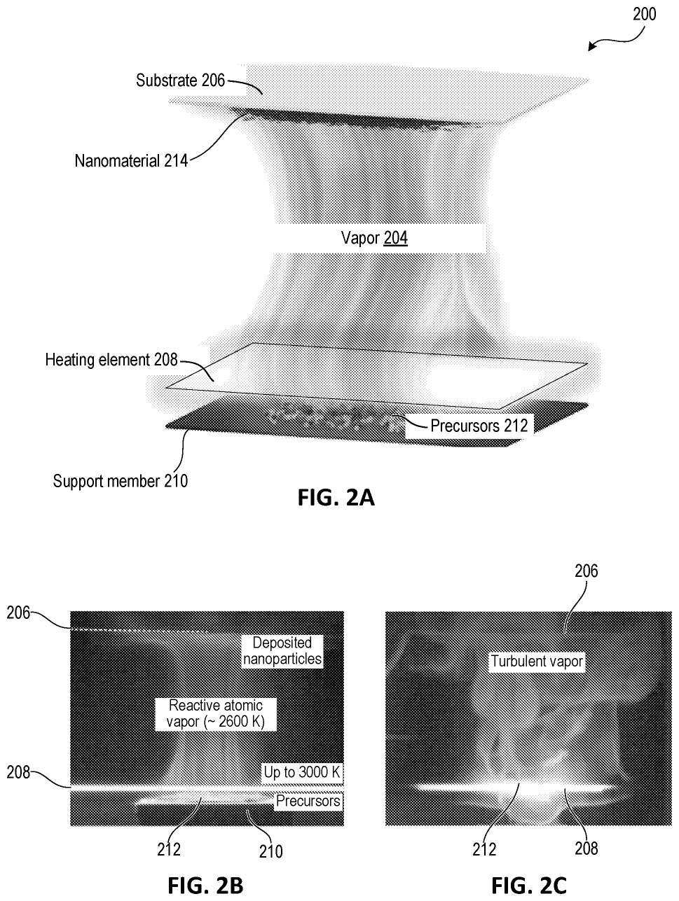

Referring to FIGS. 2A-2B, operation of a fabricated vapor deposition setup 200 is shown. When heated by the Joule heating element 208 (e.g., at a temperature of ˜ 3000 K), the precursors 212 are vaporized into high-flux atomic species. This high temperature atomic vapor 204 expands and flows from the open edges between the support member 210 and the heating element 208, convecting upwards and mixing with the surrounding room-temperature gas until the resulting atomic and molecular intermediate species nucleate and grow into the final product 214 on the suspended deposition substrate 206 (e.g., carbon paper) at a lower temperature (e.g., ˜600 K). In some embodiments, the product 214 comprises one or more nanomaterials. For example, the nanomaterials can each have an aspherical shape, for example, as hexagonal nanodisks, polyhedrons, or rectangular prisms.

In some embodiments, by providing the precursors in the semi-confined volume between the support member 210 and a baffle member (e.g., the heating element 208), a stable flow of vapor 204 can be formed. Moreover, the vapor 204 can be spatially-confined as it flows from the heating element 208 toward the substrate 206 without any intervening physical structure used to provide such confinement (e.g., without flow channel or bottleneck curvature to direct the flow at the substrate). In contrast, when the precursors are not provided in a semi-confined volume, the resulting vapor may not be spatially-confined. For example, as shown in FIG. 2C, precursors 212 placed on the heating element 208 without a baffle member between the precursors and the deposition substrate 206 resulted in a turbulent vapor flow with poor spatial confinement, which made the material harder to collect on the deposition substrate 206 since the vapor convected in various directions.

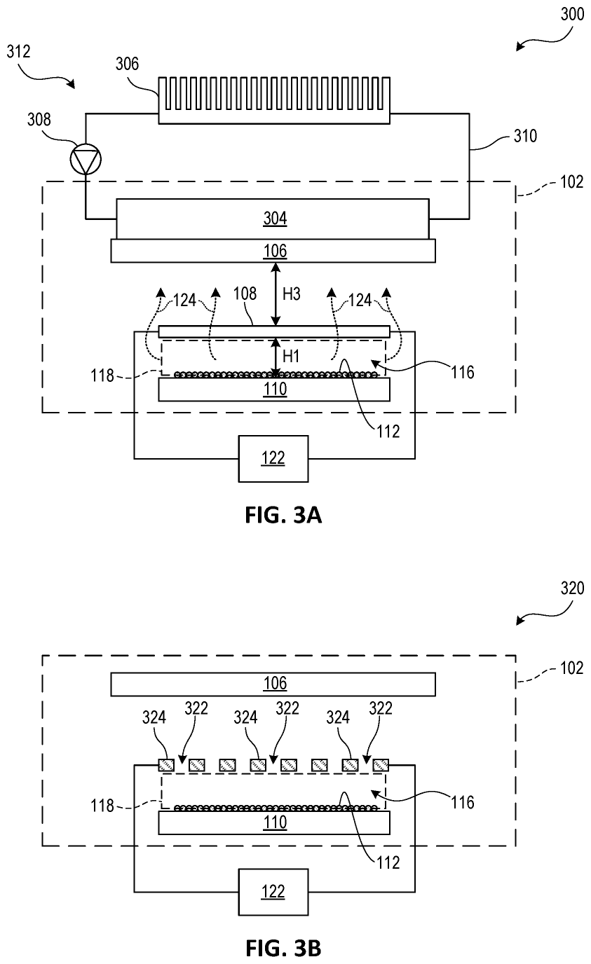

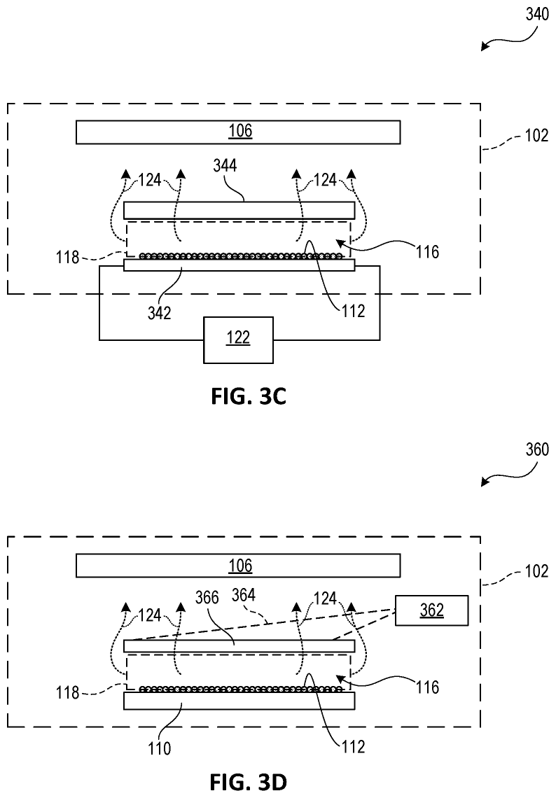

As noted above, in some embodiments, the deposition substrate 106 can be cooled via active or passive means. For example, FIG. 3A shows a vapor deposition system 300 that employs active cooling of the deposition substrate 106 by cooling system 312. In the illustrated example, cooling system 312 can include a cooling plate 304 thermally coupled to the deposition substrate 106, a heat exchanger 306 connected to the cooling plate 304 via a flow circuit 310 for a heat transfer fluid, and a pump 308 for moving the heat transfer fluid through the flow circuit 310. Alternatively, pump 308 can be omitted in favor of relying on a thermosiphon effect to move the heat transfer fluid through the flow circuit 310. Although a specific cooling system configuration is illustrated in FIG. 3A, embodiments of the disclosed subject matter are not limited thereto. Rather, similar effect can be achieved by employing other cooling system configurations, such as but not limited to a heat pump, thermoelectric cooling module, or a plate fin heat exchanger coupled to the back of the deposition substrate.

In some embodiments, by cooling the deposition substrate 106, the duration t_{H} of the heating period 134 can be increased and/or the duration t_{H} of the no-heating period 136 can be reduced (or even omitted altogether). Alternatively or additionally, in some embodiments, the cooling of the deposition substrate 106 can allow the deposition substrate 106 to be disposed closer to the precursors 112 and/or the heating element (e.g., baffle member 108). For example, the deposition substrate 106 can be disposed at a distance H3 from the baffle member 108, where H3 can be less than the distance H2 in FIG. 1A.

In some embodiments, multiple heating elements (or heating element portions) can be provided instead of single heating element. For example, FIG. 3B illustrates a vapor deposition system 320 that employs a plurality of heating element portions 324 separated from each other by gaps 322. In some embodiments, the gaps 322 can serve as additional exit windows (in addition to exit window 118) from the confined heating volume 116. Alternatively or additionally, the gaps 322 can be random or regularly-spaced pores within an otherwise continuous heating element (e.g., a porous carbon paper). In some embodiments, a size of the gaps 322 may be smaller (e.g., an order of magnitude smaller) than a size of the exit windows 118, such that most or at least a majority of the generated vapor exits the confined heating volume 116 via the windows 118.

Although the discussion above has focused on the baffle member (or a portion thereof) providing the heating to generate the ultrahigh temperatures for vapor generation, embodiments of the disclosed subject matter are not limited thereto. Rather, in some embodiments, the baffle member may be entirely passive (e.g., without any heating element), and the heating element can be provided elsewhere in the system. For example, FIG. 3C illustrates a vapor deposition system 340 where the support member 342 (or at least a portion thereof) operates as the heating element and baffle member 344 is passive. Thus, the solid-state precursors 112 can be disposed on the heating element, while the support member 342 and the passive baffle member 344 continue to define the confined heating volume 116 that urges the vapor into a spatially-confined flow (e.g., non-turbulent).

Other configurations for the heating element are also possible. Indeed, although the discussion above and elsewhere herein focuses on Joule heating elements, embodiments of the disclosed subject matter are not limited thereto. Indeed, other heating modalities capable of generating the ultrahigh temperatures and rapid heating are also possible according to one or more contemplated embodiments. For example, the heating to provide the vapor generating temperature can be performed by a Joule heating element, a microwave heating source, a laser, an electron beam device, a spark discharge device, or any combination of the foregoing. For example, FIG. 3D shows a vapor deposition system 360 that employs a separate heating system 362 and a passive baffle member 366. In the illustrated example, the heating system 362 (e.g., laser, microwave source, electron beam source, etc.) can direct heating radiation 364 at the baffle member 366 to increase a temperature thereof to the vapor generating temperature. Alternatively or additionally, the support member 110 and/or the precursors 112 can be irradiated by heating system 362 to increase a temperature thereof.

In some embodiments, precursors vaporized from the support member can be replaced with additional precursors (e.g., to enable further deposition of similar composition nanomaterials or layers) or with different precursors (e.g., to enable deposition of different composition nanomaterials or layers). Alternatively or additionally, in some embodiments, the deposition substrate or a portion thereof can be replaced with a fresh substrate or a fresh portion, for example, to allow further nanomaterial or layer deposition. In some embodiments, the precursors, deposition substrates, and/or deposition substrate portions can be provided via a conveyor mechanism (e.g., a roll-to-roll configuration to allow for continuous manufacturing).

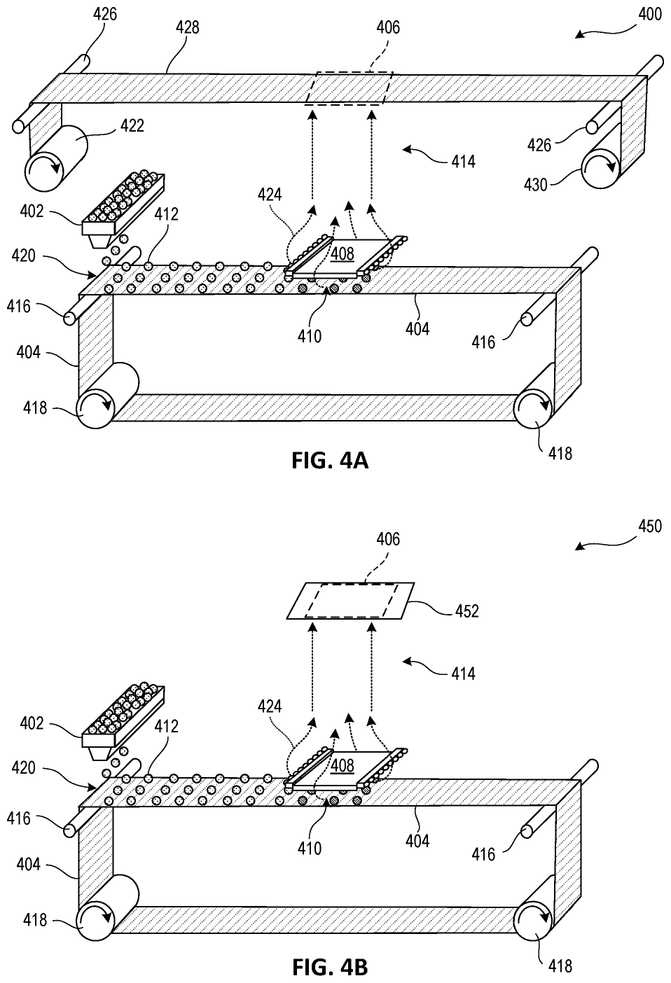

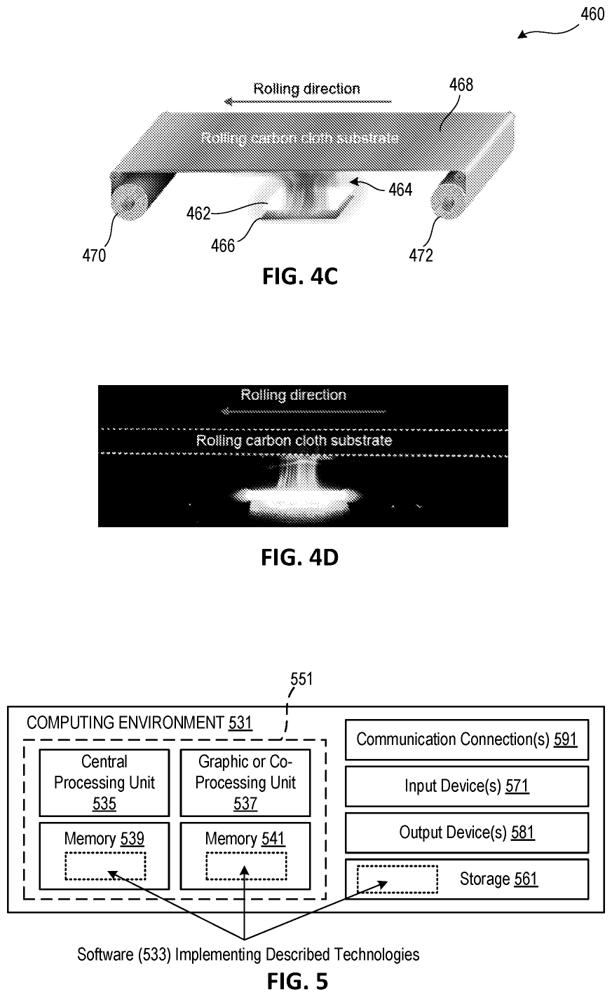

For example, FIG. 4A illustrates a conveyor-based vapor deposition system 400 that includes a first conveyor mechanism for advancing fresh precursors 412 to the confined heating volume 410 for vaporization and a second conveyor mechanism for advancing different substrate portions for sequential nanomaterial deposition. The first conveyor mechanism can include a first roller member 404 that is driven by one or more drive rollers 418 and positioned via one or more redirection rollers 416. The first roller member 404 can support the precursors 412 thereon and be spaced from a baffle member 408 so as to define the confined heating volume 410. Fresh precursors 412 can be provided from a dispenser 402 to the first roller member 404 in an inlet zone 420, and the first roller member advanced until the precursors 412 are disposed within the confined heating volume 410. A portion of the baffle member 408 can operate as a heating element (e.g., Joule heating element) to subject the precursors 412 in the confined heating volume 410 to the vapor generating temperature, thereby producing vapor 424.

The second conveyor mechanism can include an input substrate roller 422 that provides, via redirection roller 426, fresh portions of a second roller member 428 to vapor deposition region 406 to serve as a deposition substrate portion (e.g., a surface portion of the second roller member 428 facing the reaction zone 414 in the deposition region 406 so as to receive the generated vapor 424). Once nanomaterials are formed on the deposition substrate portion, the second roller member 428 can be moved to the output substrate roller 430, via another redirection roller 426, for storage, subsequent processing, and/or use.

In some embodiments, the heating may be substantially continuous (e.g., without the pulsed heating of FIG. 1B), and/or the advancement of the first roller member 404 may be substantially continuous and at a rate that provides fresh precursors to the confined heating volume 410 as previous precursors are consumed. In some embodiments, the advancement of the second roller member 428 may also be substantially continuous and at a rate, for example, that maintains an average temperature of the portion of the second roller member 428 within the deposition region 406 below a predetermined threshold (e.g., <1000 K, such as ˜ 600 K). For example, portions of the second roller member 428 outside of the deposition region 406 may be exposed to temperatures less than the portion of the second roller member 428 within the deposition region 406, such that continuously (or periodically) replacing the portion within the deposition region 406 can ensure the temperature at the deposition surface remains low enough to support efficient deposition. In some embodiments, the moving of the second roller member 428 to mitigate high temperature concentration can avoid, or at least reduce, the need for separate cooling of the deposition substrate in the vapor deposition region and/or pulsed operation of the heating element. Alternatively, in some embodiments, the heating may be periodic (e.g., the pulsed heating of FIG. 1B), and the advancement of the first roller member 404 and/or the second roller member 428 may be similarly periodic (e.g., stopping during the heating period and advancing during the no-heating period).

Although conveyor mechanisms are employed for both the precursor support member and the deposition substrate in FIG. 4A, embodiments of the disclosed subject matter are not limited thereto. Rather, in some embodiments, the conveyor mechanism may be employed for the precursors only, for example, as with system 450 of FIG. 4B. In such a configuration, a static deposition substrate 452 can be provided within deposition region 406, and the deposition substrate 452 can be replaced with a fresh substrate once vapor deposition has been completed. Alternatively or additionally, the conveyor mechanism may be employed for the deposition substrate only, for example, as with system 460 of FIG. 4C. In such a configuration, the precursor support member 466 is static underneath the baffle member 462 (e.g., with Joule heating element), and the generated vapor 464 can be deposited on the deposition substrate 468 (e.g., carbon cloth) as it moves between an input roller 472 and an output roller 470. Other vapor deposition system configurations and variations are also possible according to one or more contemplated embodiments.

### Computer Implementation

FIG. 5 depicts a generalized example of a suitable computing environment 531 in which the described innovations may be implemented, such as but not limited to aspects of a vapor deposition method, controller 120, and/or a controller of a vapor deposition system (e.g., setup 200, system 300, system 320, system 340, system 360, system 400, system 450, and/or system 460). The computing environment 531 is not intended to suggest any limitation as to scope of use or functionality, as the innovations may be implemented in diverse general-purpose or special-purpose computing systems. For example, the computing environment 531 can be any of a variety of computing devices (e.g., desktop computer, laptop computer, server computer, tablet computer, etc.).

With reference to FIG. 5, the computing environment 531 includes one or more processing units 535, 537 and memory 539, 541. In FIG. 5, this basic configuration 551 is included within a dashed line. The processing units 535, 537 execute computer-executable instructions. A processing unit can be a central processing unit (CPU), processor in an application-specific integrated circuit (ASIC), or any other type of processor (e.g., hardware processors, graphics processing units (GPUs), virtual processors, etc.). In a multi-processing system, multiple processing units execute computer-executable instructions to increase processing power. For example, FIG. 5 shows a central processing unit 535 as well as a graphics processing unit or co-processing unit 537. The tangible memory 539, 541 may be volatile memory (e.g., registers, cache, RAM), non-volatile memory (e.g., ROM, EEPROM, flash memory, etc.), or some combination of the two, accessible by the processing unit(s). The memory 539, 541 stores software 533 implementing one or more innovations described herein, in the form of computer-executable instructions suitable for execution by the processing unit(s).

A computing system may have additional features. For example, the computing environment 531 includes storage 561, one or more input devices 571, one or more output devices 581, and one or more communication connections 591. An interconnection mechanism (not shown) such as a bus, controller, or network interconnects the components of the computing environment 531. Typically, operating system software (not shown) provides an operating environment for other software executing in the computing environment 531, and coordinates activities of the components of the computing environment 531.

The tangible storage 561 may be removable or non-removable, and includes magnetic disks, magnetic tapes or cassettes, CD-ROMs, DVDs, or any other medium which can be used to store information in a non-transitory way, and which can be accessed within the computing environment 531. The storage 561 can store instructions for the software 533 implementing one or more innovations described herein.

The input device(s) 571 may be a touch input device such as a keyboard, mouse, pen, or trackball, a voice input device, a scanning device, or another device that provides input to the computing environment 531. The output device(s) 571 may be a display, printer, speaker, CD-writer, or another device that provides output from computing environment 531.

The communication connection(s) 591 enable communication over a communication medium to another computing entity. The communication medium conveys information such as computer-executable instructions, audio or video input or output, or other data in a modulated data signal. A modulated data signal is a signal that has one or more of its characteristics set or changed in such a manner as to encode information in the signal. By way of example, and not limitation, communication media can use an electrical, optical, radio-frequency (RF), or another carrier.

Any of the disclosed methods can be implemented as computer-executable instructions stored on one or more computer-readable storage media (e.g., one or more optical media discs, volatile memory components (such as DRAM or SRAM), or non-volatile memory components (such as flash memory or hard drives)) and executed on a computer (e.g., any commercially available computer, including smart phones or other mobile devices that include computing hardware). The term computer-readable storage media does not include communication connections, such as signals and carrier waves. Any of the computer-executable instructions for implementing the disclosed techniques as well as any data created and used during implementation of the disclosed embodiments can be stored on one or more computer-readable storage media. The computer-executable instructions can be part of, for example, a dedicated software application or a software application that is accessed or downloaded via a web browser or other software application (such as a remote computing application). Such software can be executed, for example, on a single local computer (e.g., any suitable commercially available computer) or in a network environment (e.g., via the Internet, a wide-area network, a local-area network, a client-server network (such as a cloud computing network), or any other such network) using one or more network computers.

For clarity, only certain selected aspects of the software-based implementations are described. Other details that are well known in the art are omitted. For example, it should be understood that the disclosed technology is not limited to any specific computer language or program. For instance, aspects of the disclosed technology can be implemented by software written in C++, Java™, Python®, and/or any other suitable computer language. Likewise, the disclosed technology is not limited to any particular computer or type of hardware. Certain details of suitable computers and hardware are well known and need not be set forth in detail in this disclosure.

It should also be well understood that any functionality described herein can be performed, at least in part, by one or more hardware logic components, instead of software. For example, and without limitation, illustrative types of hardware logic components that can be used include Field-programmable Gate Arrays (FPGAs), Program-specific Integrated Circuits (ASICs), Program-specific Standard Products (ASSPs), System-on-a-chip systems (SOCs), Complex Programmable Logic Devices (CPLDs), etc.

Furthermore, any of the software-based embodiments (comprising, for example, computer-executable instructions for causing a computer to perform any of the disclosed methods) can be uploaded, downloaded, or remotely accessed through a suitable communication means. Such suitable communication means include, for example, the Internet, the World Wide Web, an intranet, software applications, cable (including fiber optic cable), magnetic communications, electromagnetic communications (including RF, microwave, and infrared communications), electronic communications, or other such communication means. In any of the above-described examples and embodiments, provision of a request (e.g., data request), indication (e.g., data signal), instruction (e.g., control signal), or any other communication between systems, components, devices, etc. can be by generation and transmission of an appropriate electrical signal by wired or wireless connections.

### Fabricated Examples and Experimental Results

To demonstrate the synthesis capabilities of the disclosed vapor deposition techniques, various multi-element products were fabricated using the vapor deposition setup 200 of FIG. 2A. To form the heating element 208, a sheet of carbon paper (AvCarb® MGL370, density of 0.46 g/cm³, porosity of 78%, electrical resistivity of 75 mΩ·cm) was cut to a planar size of about 10 cm×2 cm (thickness of 0.37 mm). The center of the carbon paper was then further cut to form a narrow strip with a planar size of about 5 cm×0.7 cm (thickness of 0.37 mm). This narrowed strip at the center of the paper has a higher electrical resistance than the surrounding material, thereby creating a concentrated heating zone where the temperature can reach ˜3000 K. Using two copper clips, the carbon heating element was connected to a high-power DC source with tunable current (0-50 A) and voltage (0-100 V). Precursors were loaded on support member 210 (e.g., a graphite disk) placed ˜1 mm below the heating element 208. For the deposition substrate 206, a separate piece of carbon paper (AvCarb® MGL190, thickness of 0.19 mm, density of 0.44 g/cm³, porosity of 78%, electrical resistivity of 75 m (2·cm) with a planar size of 5 cm×2.5 cm was placed above the heating element 208 (e.g., 2-6 cm from the heating element. The setup 200 was contained in a glove box that maintained an inert gas environment (e.g., Ar and/or N₂).

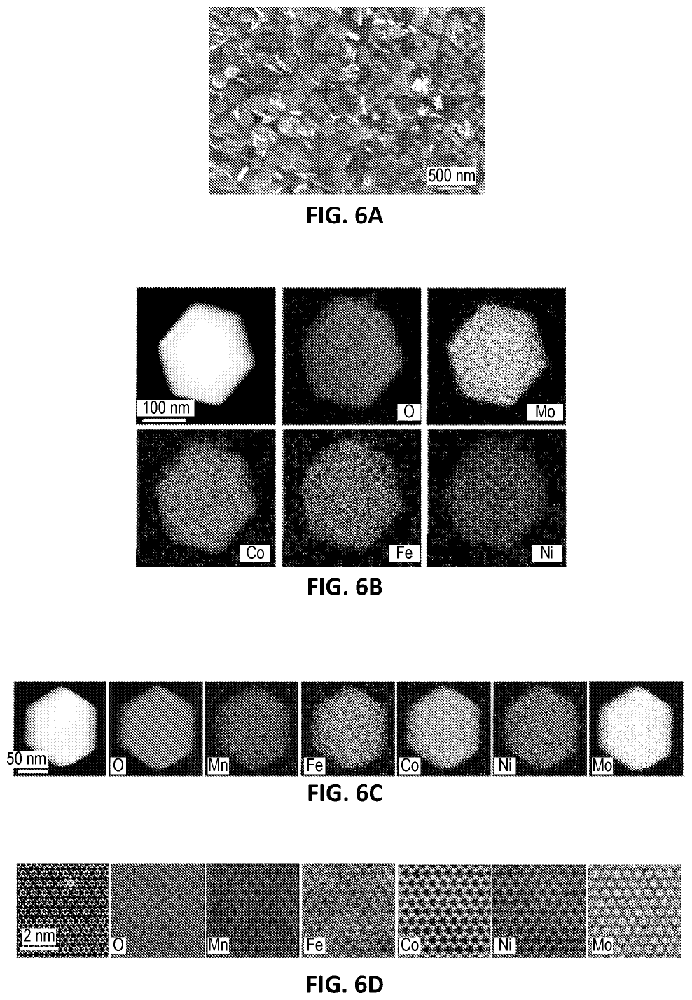

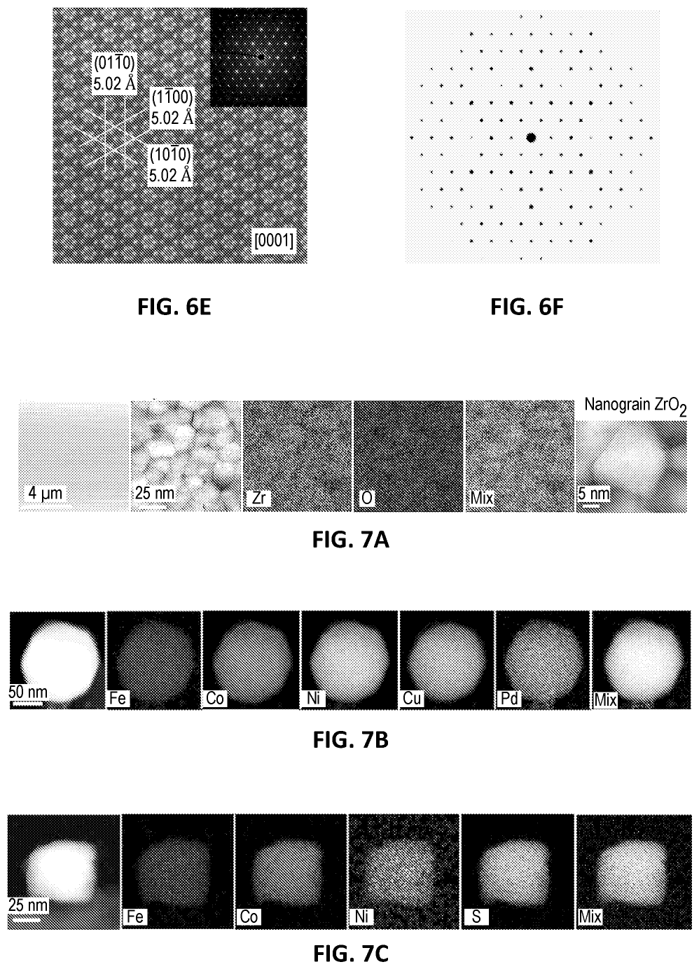

To form the nanomaterials, appropriate precursors (e.g., multi-elemental salts, such as but not limited to MClₓ, where M is a metal) were physically mixed in desired ratios and loaded onto the support member 210. In one fabricated example, crystalline multi-elemental (quinary) nanodisks were formed and composed of Mo₄₅Co₂₅Fe_{y}Ni_{y}Mn_{30-2y}Oₓ (with y=10, 12.5, or 15), in which each element is uniformly distributed throughout, as shown in FIGS. 6A-6B. As shown in the HAADF-STEM and STEM-EDS of FIGS. 6C-6D, the nanodisks possess uniform elemental distribution throughout with no apparent elemental segregation or phase separation. In addition, as shown in the STEM-EDS of FIG. 6D, the composition of M₄₅Co₂₅Fe₁₀Ni₁₀Mn₁₀Oₓ nanodisks is very close to that of the initial precursor molar ratios, demonstrating the strong composition control of the disclosed vapor deposition technique. This unique multi-elemental crystalline nanodisk structure has not previously observed and is made possible by the fast nucleation and crystallization on the substrate from the continuous flow of the ultrahigh-temperature, multi-elemental vapor with fast temperature quenching that prevents phase separation. Such crystalline nanodisks may have potential application in magnetics or catalysis, among other applications.

The HAADF-STEM of FIG. 6C further shows a single-crystal hexagonal structure. As shown in FIG. 6E, the hexagonal single-crystal exhibits a d-spacing of 5.02 Å for the (10-10), (1-100), and (01-10) lattice planes. The corresponding selected area electron diffraction (SAED) results confirmed the hexagonal nature of the multi-elemental oxide nanodisks, with a space group of P₆₃ₘₑ, as shown in the inset of FIG. 6E. As shown by a comparison of FIGS. 6E-6F, the diffraction pattern of Mo₄₅Co₂₅Fe_{y}Ni_{y}Mn_{30-2y}Oₓ matches that of Co₂Mo₃O₈ (hexagonal, P_{63mc}) at the zone axis, indicating that the Mo₄₅Co₂₅Fe_{y}Ni_{y}Mn_{30-2y}Oₓ may also feature a A₂B₃O₈ (hexagonal P_{63mc}) structure. Additionally, based on the high-resolution HAADF-STEM and STEM-EDS results shown in FIGS. 6C-6D, it was found that Mo primarily occupies the B sites and that Co and Ni predominately occupy the A sites, while Mn and Fe appear to reside at both sites. These results demonstrate how the non-equilibrium conditions (e.g., high temperature and rapid heating/cooling) of the solid-to-vapor-to-solid transformation during the disclosed vapor deposition technique can enable multi-elemental nanomaterials to be formed and kinetically trapped, remaining stable at room temperature with single-crystal structure.

In the vapor deposition synthesis, the size of the particle products can be tuned by varying the height of the deposition substrate with respect to the baffle member (e.g., heating element) in order to control the nucleation and growth process. For example, at a relatively low height of 3 cm, the size distribution of the Mo₄₅Co₂₅Fe₁₀Ni₁₀Mn₁₀Oₓ nanodisks is relatively uniform, with an average size of ˜120 nm±10 nm. As the distance between the baffle member and the deposition substrate is increased to 4 cm, the nanodisk size also increases to ˜ 156 nm and the distribution broadens to ±27 nm. When the distance is further increased to 5 cm, the size of the nanodisks continues to increase with an even broader distribution, e.g., ˜237 nm±60 nm. Without wishing to be bound by any particular theory, the size control can be attributed to the vaporized atomic species having more time to recombine into intermediate species as the distance between the heating element and the deposition substrate is increased. As more intermediates form, they will collide and produce even larger intermediates, which can then nucleate and grow into larger nanodisks on the substrate.

The vapor deposition technique can be used to fabricate a wide range of nanomaterials and compositions, with uniform mixing of elemental species without phase segregation (e.g., a metastable state). In a fabricated example, CuNi binary alloy spherical nanoparticles were formed, with both elements being uniformly distributed in each nanoparticle. In another fabricated example, CuCoNiPtIr high entropy alloy (e.g., having at least 5 different elements) nanoparticles were formed, with all elements uniformly distributed in each nanoparticle. In yet another fabricated example, a homogeneous ZrO₂ film was formed on the deposition substrate, where the film was composed of nanograin ZrO₂ that crystallized into a continuous coating as shown in FIG. 7A.

In another fabricated example, FeCoNiCuPd high-entropy alloy nanoparticles were fabricated by vaporizing mixed MCIₓ (M=Fe, Co, Ni, Cu, Pd) precursors at ˜2700 K. The vapor was collected by the carbon paper substrate suspended ˜3 cm above the heating element. The resulting nanoparticles feature a polyhedron shape, in which each element is uniformly distributed, as shown in FIG. 7B. Additionally, the normally immiscible metals of Co and Cu were uniformly mixed in the particles, which can be attributed to the highly non-equilibrium nature of the vapor deposition process (e.g., high temperature and rapid heating/cooling rates). Such metallic alloys are typically not possible by conventional flame synthesis, which generally uses oxygen to produce the flame, thus limiting reaction products to metal oxide and carbon-based materials. Although the above-noted examples describe metal oxide and alloy nanoparticles, embodiments of the disclosed subject matter are not limited thereto. For example, multi-element sulfide nanoparticles can be formed. In another fabricated example, sulfide high entropy hexagonal nanoparticles were formed and having a composition of CuCoNiFeMnSₓ. In another fabricated example, FeCoNiS nanoparticles were formed with each element uniformly distributed, as shown in FIG. 7C.

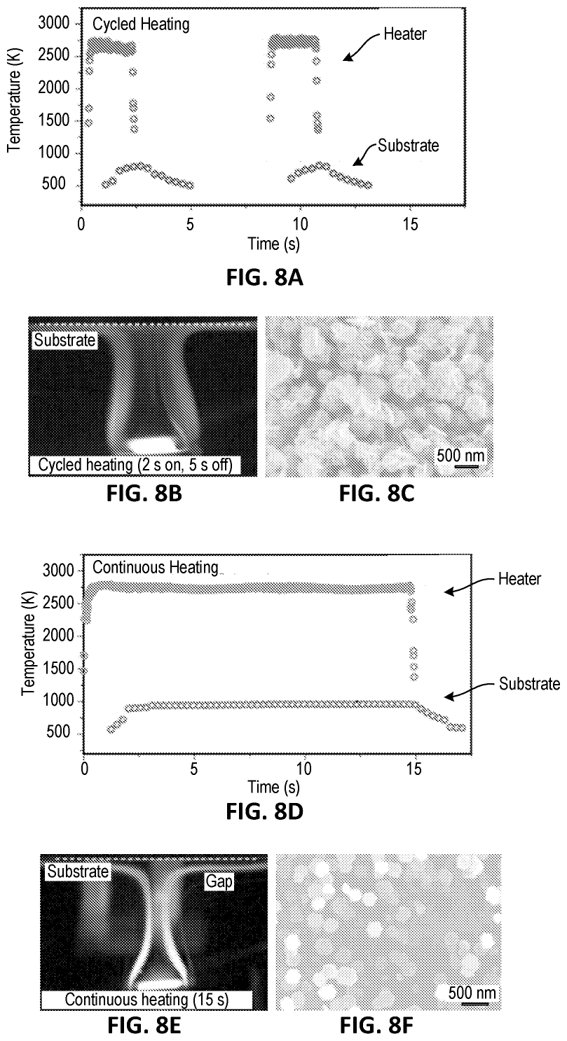

The ability to effectively deposit vapors on the deposition substrate can depend on the substrate temperature, as a sufficiently cool substrate may encourage the vaporized species to deposit. To avoid overheating the overlying deposition substrate and provide effective sample deposition, the heating element was cycled on and off. As shown in FIG. 8A, the average temperature of the substrate was maintained at ˜600 K by ramping the heating element to ˜2700 K (e.g., at a high heating rate of ˜10+K/s), maintain the temperature for 2 seconds, and then turning the heating element off for 5 seconds. Under these conditions, the atomic vapor tends to condense into a solid phase on the relatively cool deposition substrate, as shown in FIG. 8B. As shown in FIG. 8C, cyclic heating results in a thick coating of Mo₄₅Co₂₅Fe₁₀Ni₁₀Mn₁₀Oₓ nanodisks.

In contrast, if the heating element is maintained at 2700 for ˜15 seconds, the deposition substrate reaches a temperature of ˜1000 K, as shown in FIG. 8D. At this higher temperature, there are competing flow effects, as the inert gas surrounding the substrate is heated and expands against the flow of the atomic vapor. As shown in FIG. 8E, this forms a clear gap between the vapor flow and substrate that can diminish deposition. Additionally, the higher temperature can make it difficult for the vapor phase species to condense into the solid phase on the substrate surface. As a result, fewer Mo₄₅Co₂₅Fe₁₀Ni₁₀Mn₁₀Oₓ nanodisks were deposited under these conditions, as shown in FIG. 8F.

We hypothesize this substrate temperature effect is also why the distance between the heater and substrate must be kept above ˜2 cm to ensure effective sample deposition (Figure S6A). Below this critical distance, the temperature of the substrate is too hot (˜2000 K), which prevents product nucleation (Figure S6B, C). However, the substrate cannot be placed too high either. For example, above 6 cm, particle deposition is also poor (Figure S6D, E), which we hypothesize is due to the excessive growth of particles in the vapor phase, which may be too heavy to be collected effectively. Note that this 2-6 cm range is based on the particular configuration of the vapor deposition system in FIG. 2A, as well as precursors for forming the nanomaterials. Other system configurations (e.g., where the baffle member is not a heating element) and/or materials (e.g., fewer elements) may result in different ranges to yield effective formation of nanomaterials. Alternatively, employing cooling (e.g., active or passive cooling) can further alter the range of spacing between the baffle member and the deposition substrate.

The disclosed vapor deposition technique can be readily scaled for production of multi-elemental nanomaterials, for example, via a roll-to-roll production system. As proof-of-concept, a roll-to-roll system 460 was made, as shown in FIGS. 4C-4D. The system 460 had a rolling carbon cloth substrate 468 disposed above a heating element 462. The rolling carbon cloth substrate 468 was fed from an input roller 472 and collected after nanomaterial deposition by an output roller 470. Precursors (e.g., multi-elemental metallic salts) were disposed on a support member 466. By heating the precursors at ˜2700 K, a vapor phase 464 of atomic species was generated with a steady, upward flow to the carbon cloth 468, enabling continuous nucleation and growth of nanomaterials on the moving substrate. Even without process optimization, Mo₄₅Co₂₅Fe₁₅Ni₁₅Oₓ nanodisks could be successfully synthesized using this roll-to-roll system, demonstrating the robustness and scalability of vapor deposition technique.

### Additional Examples of the Disclosed Technology

In view of the above-described implementations of the disclosed subject matter, this application discloses the additional examples in the clauses enumerated below. It should be noted that one feature of a clause in isolation, or more than one feature of the clause taken in combination, and, optionally, in combination with one or more features of one or more further clauses are further examples also falling within the disclosure of this application.
Clause 1. A method comprising:
   (a) providing a baffle member, a deposition substrate, a support member, and a first batch of solid-state precursors on the support member, the baffle member being disposed over and spaced from the support member by a first distance along a first direction, the baffle and support members being constructed and arranged so as to define a confined heating volume with at least one exit window, the deposition substrate being disposed over and spaced from the baffle member by a second distance along the first direction; and
   (b) subjecting the first batch of solid-state precursors to a first temperature greater than 2200 K, so as to convert at least some of the solid-state precursors into a vapor that exits the confined heating volume via the at least one exit window,
   wherein, during at least part of the subjecting of (b):
      the deposition substrate is at a second temperature less than the first temperature, and
      the exiting vapor flows around the baffle member into contact with a surface of the deposition substrate such that the vapor solidifies on said deposition substrate surface.
Clause 2. The method of any clause or example herein, in particular, Clause 1, wherein the vapor solidifies on said deposition substrate surface to form one or more nanomaterials.
Clause 3. The method of any clause or example herein, in particular, Clause 2, wherein the one or more nanomaterials have a maximum cross-sectional dimension less than or equal to 500 nm.
Clause 4. The method of any clause or example herein, in particular, any one of Clauses 2-3, wherein the one or more nanomaterials have a maximum cross-sectional dimension in a range of 100-300 nm, inclusive.
Clause 5. The method of any clause or example herein, in particular, any one of Clauses 2-4, wherein each of the one or more nanomaterials has an aspherical shape.
Clause 6. The method of any clause or example herein, in particular, any one of Clauses 2-5, wherein at least some of the one or more nanomaterials are shaped as polyhedrons or rectangular prisms.
Clause 7. The method of any clause or example herein, in particular, any one of Clauses 2-6, wherein at least some of the one or more nanomaterials are shaped as hexagonal disks.
Clause 8. The method of any clause or example herein, in particular, any one of Clauses 2-7, wherein at least some of the one or more nanomaterials are single-crystal structures.
Clause 9. The method of any clause or example herein, in particular, any one of Clauses 2-8, wherein at least some of the one or more nanomaterials exhibit uniform elemental mixing without phase segregation.
Clause 10. The method of any clause or example herein, in particular, any one of Clauses 2-9, wherein the providing of (a) comprises selecting the second distance based at least in part on a desired particle size for the one or more nanomaterials.
Clause 11. The method of any clause or example herein, in particular, Clause 1, wherein the vapor solidifies on said deposition surface to form a coating.
Clause 12. The method of any clause or example herein, in particular, any one of Clauses 1-11, wherein the baffle member comprises a heating element that generates the first temperature during the subjecting of (b).
Clause 13. The method of any clause or example herein, in particular, Clause 12, wherein the heating element generates the first temperature via Joule heating.
Clause 14. The method of any clause or example herein, in particular, any one of Clauses 12-13, wherein the heating element comprises a porous carbon member.
Clause 15. The method of any clause or example herein, in particular, any one of Clauses 1-12, wherein, during at least part of the subjecting of (b), the first temperature is generated by a Joule heating element, a microwave heating source, a laser, an electron beam device, a spark discharge device, or any combination of the foregoing.
Clause 16. The method of any clause or example herein, in particular, any one of Clauses 1-15, wherein, during at least part of the subjecting of (b), the vapor forms a spatially-confined flow in a region between the baffle member and the deposition substrate.
Clause 17. The method of any clause or example herein, in particular, Clause 16, wherein the spatially-confined flow is formed without a physically confining structure between the baffle member and the deposition substrate.
Clause 18. The method of any clause or example herein, in particular, any one of Clauses 1-17, wherein, during at least part of the subjecting of (b), the flow of the vapor into contact with the deposition substrate surface is buoyancy driven.
Clause 19. The method of any clause or example herein, in particular, any one of Clauses 1-18, wherein the second distance is greater than the first distance, the second distance is at least 10 times the first distance, the second distance is less than or equal to 10 cm, the second distance is in a range of 2-6 cm, inclusive, or any combination of the foregoing.
Clause 20. The method of any clause or example herein, in particular, any one of Clauses 1-19, wherein the first distance is less than or equal to 10 mm, the first distance is in a range of 100 μm to 2 mm, inclusive, the first distance is about 1 mm, or any combination of the foregoing.
Clause 21. The method of any clause or example herein, in particular, any one of Clauses 1-20, wherein the at least one exit window is defined by a vertical gap between the baffle member and the support member.
Clause 22. The method of any clause or example herein, in particular, any one of Clauses 1-21, wherein the first direction is substantially parallel to a direction of gravity.
Clause 23. The method of any clause or example herein, in particular, any one of Clauses 1-22, wherein the first temperature is in a range of 2500-3000 K, inclusive, the second temperature is less than or equal to 1000 K, or any combination of the foregoing.
Clause 24. The method of any clause or example herein, in particular, any one of Clauses 1-23, wherein the second temperature is an average temperature of the deposition substrate surface during the subjecting of (b), and the second temperature is less than or equal to 600 K.
Clause 25. The method of any clause or example herein, in particular, any one of Clauses 1-24, wherein the subjecting of (b) comprises heating to the first temperature at a heating rate in a range of 102 to 105 K/s, inclusive, the subjecting of (b) comprises heating to the first temperature at a heating rate of about 104 K/s, or any combination of the foregoing.
Clause 26. The method of any clause or example herein, in particular, any one of Clauses 1-25, wherein the subjecting of (b) is performed in an inert gas environment.
Clause 27. The method of any clause or example herein, in particular, any one of Clauses 1-26, wherein a size of the baffle member in a plane perpendicular to the first direction is less than a size of the deposition substrate in the plane perpendicular to the first direction.
Clause 28. The method of any clause or example herein, in particular, any one of Clauses 1-27, wherein the deposition substrate, the support member, the baffle member, or any combination of the foregoing is formed of a refractory material.
Clause 29. The method of any clause or example herein, in particular, any one of Clauses 1-28, wherein the deposition substrate, the support member, the baffle member, or any combination of the foregoing is formed of carbon.
Clause 30. The method of any clause or example herein, in particular, any one of Clauses 1, wherein the subjecting of (b) comprises:
   (b1) subjecting the first batch of solid-state precursors to the first temperature for a first time duration;
   (b2) after (b1), ceasing heating such that a temperature of the solid-state precursors decreases over a second time duration; and
   (b3) repeating (b1) and (b2).
Clause 31. The method of any clause or example herein, in particular, Clause 30, wherein the second time duration is greater than the first time duration, the second time duration is at least 2 times the first time duration, each of the first and second time durations is less than or equal to 5 seconds, the first time duration is in a range of about 100 milliseconds to about 2 seconds, inclusive, the second time duration is about 5 seconds, or any combination of the foregoing.
Clause 32. The method of any clause or example herein, in particular, any one of Clauses 1-31, wherein the vapor comprises atomic species of the solid-state precursors.
Clause 33. The method of any clause or example herein, in particular, any one of Clauses 1-32, wherein the first batch of solid-state precursors comprises one or more metal salts.
Clause 34. The method of any clause or example herein, in particular, Clause 33, wherein the one or more metal salts have a formula of MClₓ, where M is a metal and x is an integer.
Clause 35. The method of any clause or example herein, in particular, Clause 34, wherein M is selected from the group consisting of Mo, Co, Fe, Ni, Mn, Pd, Cu, Pt, Ir, and Zr.
Clause 36. The method of any clause or example herein, in particular, any one of Clauses 1-35, wherein the vapor solidifies on said deposition substrate surface to form individual multielement nanoparticles, each nanoparticle comprising at least Mo, Mn, Fe, Co, and Ni.
Clause 37. The method of any clause or example herein, in particular, any one of Clauses 1-36, wherein the vapor solidifies on said deposition substrate surface to form individual MoMnFeCoNiOₓ high-entropy-oxide hexagonal nanodisks.
Clause 38. The method of any clause or example herein, in particular, any one of Clauses 1-35, wherein the vapor solidifies on said deposition substrate surface to form individual FeCoNiS or CuCoNiFeMnS nanoparticles.
Clause 39. The method of any clause or example herein, in particular, any one of Clauses 1-35, wherein the vapor solidifies on said deposition substrate surface to form individual FeCoNiCuPd high-entropy-alloy polyhedral nanoparticles.
Clause 40. The method of any clause or example herein, in particular, any one of Clauses 1-35, wherein the vapor solidifies on said deposition substrate surface to form a homogeneous ZrO₂ film.
Clause 41. The method of any clause or example herein, in particular, any one of Clauses 1-40, further comprising, during (b), displacing the deposition substrate in a direction crossing the first direction so as to expose another surface of the deposition substrate to the vapor.
Clause 42. The method of any clause or example herein, in particular, Clause 41, wherein the deposition substrate is a first roll or conveyor member.
Clause 43. The method of any clause or example herein, in particular, any one of Clauses 1-42, further comprising, after (b):
   providing a second batch of solid-state precursors to the confined heating volume; and
   subjecting the second batch of solid-state precursors to the first temperature so as to convert at least some of the solid-state precursors into a vapor that exits the confined heating volume via the at least one window, the exiting vapor flowing around the baffle member into contact with the deposition substrate such that the vapor solidifies thereon.
Clause 44. The method of any clause or example herein, in particular, Clause 43, wherein the providing the second batch comprises displacing the support member in a direction crossing the first direction so as to dispose the second batch within the confined heating volume.
Clause 45. The method of any clause or example herein, in particular, any one of Clauses 1-44, wherein the support member is a second roll or conveyor member.
Clause 46. The method of any clause or example herein, in particular, any one of Clauses 1-45, wherein the subjecting of (b) is such that the at least some of the solid-state precursors are converted from solid to vapor without an intermediate liquid phase.
Clause 47. A nanomaterial formed by the method of any clause or example herein, in particular, any one of Clauses 1-46.
Clause 48. A uniform coating formed by the method of any clause or example herein, in particular, any one of Clauses 1-46.
Clause 49. A system comprising:
   a support member constructed to hold one or more batches of solid-state precursors thereon;
   a baffle member disposed over and spaced from the support member by a first distance along a first direction, the baffle and support members being constructed and arranged to define a confined heating volume with at least one exit window;
   a deposition substrate disposed over and spaced from the baffle member by a second distance along the first direction; and
   a controller comprising one or more processors and one or more computer readable storage media,
   wherein the baffle member comprises a heating element, and
   the one or more computer readable storage media store instructions that, when executed by the one or more processors, cause the controller to control the heating element to subject a batch of solid-state precursors within the confined heating volume to a first temperature greater than 2200 K, so as to convert at least some of the solid-state precursors into a vapor that exits the confined heating volume via the at least one exit window, flows around the baffle member into contact with a surface of the deposition substrate, and solidifies on said deposition substrate surface.
Clause 50. The system of any clause or example herein, in particular, Clause 49, wherein the heating element is a Joule heating element.
Clause 51. The system of any clause or example herein, in particular, any one of Clauses 49-50, wherein the heating element comprises a porous member formed of carbon.
Clause 52. The system of any clause or example herein, in particular, any one of Clauses 49-51, wherein the heating element is constructed to heat to the first temperature at a heating rate in a range of 10² to 10⁵ K/s, inclusive, the heating element is constructed to heat to the first temperature at a heating rate of 10⁴ K/s, or any combination of the foregoing.
Clause 53. A system comprising:
   a support member constructed to hold one or more batches of solid-state precursors thereon;
   a baffle member disposed over and spaced from the support member by a first distance along a first direction, the baffle and support members being constructed and arranged to define a confined heating volume with at least one exit window;
   a deposition substrate disposed over and spaced from the baffle member by a second distance along the first direction;
   a heating system; and
   a controller operatively coupled to the heating system, the controller comprising one or more processors and one or more computer readable storage media storing instructions that, when executed by the one or more processors, cause the controller to control the heating system to subject a batch of solid-state precursors within the confined heating volume to a first temperature greater than 2200 K, so as to convert at least some of the solid-state precursors into a vapor that exits the confined heating volume via the at least one exit window, flows around the baffle member into contact with a surface of the deposition substrate, and solidifies on said deposition substrate surface.
Clause 54. The system of any clause or example herein, in particular, Clause 53, wherein the heating system comprises a Joule heating element, a microwave heating source, a laser, an electron beam device, a spark discharge device, or any combination of the foregoing.
Clause 55. The system of any clause or example herein, in particular, any one of Clauses 49-54, wherein the vapor that exits the confined heating volume forms a spatially-confined flow without a physically-confining structure between the baffle member and the deposition substrate.
Clause 56. The system of any clause or example herein, in particular, any one of Clauses 49-55, wherein the second distance is greater than the first distance, the second distance is at least 10 times the first distance, the second distance is less than or equal to 10 cm, the second distance is in a range of 2-6 cm, inclusive, any combination of the foregoing.
Clause 57. The system of any clause or example herein, in particular, any one of Clauses 49-56, wherein the first distance is less than or equal to 10 mm, the first distance is in a range of 100 μm to 2 mm, inclusive, the first distance is about 1 mm, or any combination of the foregoing.
Clause 58. The system of any clause or example herein, in particular, any one of Clauses 49-57, wherein the at least one exit window is defined by a vertical gap between the baffle member and the support member.
Clause 59. The system of any clause or example herein, in particular, any one of Clauses 49-58, wherein the first direction is substantially parallel to a direction of gravity.
Clause 60. The system of any clause or example herein, in particular, any one of Clauses 49-59, wherein the first temperature is in a range of 2500-3000 K, inclusive.
Clause 61. The system of any clause or example herein, in particular, any one of Clauses 49-60, further comprising:
   a cooling device thermally coupled to the deposition substrate,
   wherein the controller is operatively coupled to the cooling device, and
   the one or more computer readable storage media store additional instructions that, when executed by the one or more processors, cause the controller to control the cooling device to maintain a temperature of the deposition substrate surface below 1000 K.
Clause 62. The system of any clause or example herein, in particular, Clause 61, wherein the one or more computer readable storage media store additional instructions that, when executed by the one or more processors, cause the controller to control the cooling device such that an average temperature of the deposition substrate surface is less than or equal to 600 K.
Clause 63. The system of any clause or example herein, in particular, any one of Clauses 49-62, further comprising an enclosure defining an inert gas environment, in which the support member, the baffle member, and the deposition substrate surface are disposed.
Clause 64. The system of any clause or example herein, in particular, any one of Clauses 49-63, wherein a size of the baffle member in a plane perpendicular to the first direction is less than a size of the deposition substrate in the plane perpendicular to the first direction.
Clause 65. The system of any clause or example herein, in particular, any one of Clauses 49-64, wherein the deposition substrate, the support member, the baffle member, or any combination of the foregoing is formed of a refractory material.
Clause 66. The system of any clause or example herein, in particular, any one of Clauses 49-65, wherein the deposition substrate, the support member, the baffle member, or any combination of the foregoing is formed of carbon.
Clause 67. The system of any clause or example herein, in particular, any one of Clauses 49-66, wherein the one or more computer readable storage media store instructions that, when executed by the one or more processors, cause the controller to subject the batch of solid-state precursors to the first temperature by:
   (a) subjecting the first batch of solid-state precursors to the first temperature for a first time duration;
   (b) after (a), ceasing heating such that a temperature of the solid-state precursors decreases over a second time duration; and
   (c) repeating (a) and (b).
Clause 68. The system of any clause or example herein, in particular, Clause 67, wherein the second time duration is greater than the first time duration, the second time duration is at least 2 times the first time duration, each of the first and second time durations is less than or equal to 5 seconds, the first time duration is in a range of about 100 milliseconds to about 2 seconds, inclusive, the second time duration is about 5 seconds, or any combination of the foregoing.
Clause 69. The system of any clause or example herein, in particular, any one of Clauses 49-68, further comprising:
   a first conveyor system for displacing the deposition substrate, the deposition substrate being constructed as a first roll or conveyor member,
   wherein the controller is operatively coupled to the first conveyor system, and
   the one or more computer readable storage media store instructions that, when executed by the one or more processors, cause the first conveyor system to displace the first roll or conveyor member in a direction crossing the first direction so as to expose another surface of the deposition substrate to the vapor.
Clause 70. The system of any clause or example herein, in particular, any one of Clauses 49-69, further comprising:
   a second conveyor system for displacing the support member, the support member being constructed as a second roll or conveyor member,
   wherein the controller is operatively coupled to the second conveyor system, and the one or more computer readable storage media store instructions that, when executed by the one or more processors, cause the second conveyor system to displace the second roll or conveyor member in a direction crossing the first direction so as to position another batch of solid-state precursors within the confined heating volume.

### CONCLUSION

Any of the features illustrated or described herein, for example, with respect to FIGS. 1A-8F and Clauses 1-70, can be combined with any other feature illustrated or described herein, for example, with respect to 1A-8F and Clauses 1-70 to provide materials, systems, devices, structures, methods, and/or embodiments not otherwise illustrated or specifically described herein. All features described herein are independent of one another and, except where structurally impossible, can be used in combination with any other feature described herein. In view of the many possible embodiments to which the principles of the disclosed technology may be applied, it should be recognized that the illustrated embodiments are only examples and should not be taken as limiting the scope of the disclosed technology. Rather, the scope is defined by the following claims. We therefore claim all that comes within the scope and spirit of these claims.

1. A method comprising:
(a) providing a baffle member, a deposition substrate, a support member, and a first batch of solid-state precursors on the support member, the baffle member being disposed over and spaced from the support member by a first distance along a first direction, the baffle and support members being constructed and arranged so as to define a confined heating volume with at least one exit window, the deposition substrate being disposed over and spaced from the baffle member by a second distance along the first direction; and
(b) subjecting the first batch of solid-state precursors to a first temperature greater than 2200 K, so as to convert at least some of the solid-state precursors into a vapor that exits the confined heating volume via the at least one exit window,
wherein, during at least part of the subjecting of (b):
the deposition substrate is at a second temperature less than the first temperature, and
the exiting vapor flows around the baffle member into contact with a surface of the deposition substrate such that the vapor solidifies on said deposition substrate surface.

2-11. (canceled)

12. The method of claim 1, wherein the baffle member comprises a heating element that generates the first temperature during the subjecting of (b), and the heating element generates the first temperature via Joule heating.

13-15. (canceled)

16. The method of claim 1, wherein, during at least part of the subjecting of (b), the vapor forms a spatially-confined flow in a region between the baffle member and the deposition substrate, and the spatially-confined flow is formed without a physically confining structure between the baffle member and the deposition substrate.

17. (canceled)

18. The method of claim 1, wherein, during at least part of the subjecting of (b), the flow of the vapor into contact with the deposition substrate surface is buoyancy driven.

19-20. (canceled)

21. The method of claim 1, wherein the at least one exit window is defined by a vertical gap between the baffle member and the support member.

22-29. (canceled)

30. The method of claim 1, wherein the subjecting of (b) comprises:
(b1) subjecting the first batch of solid-state precursors to the first temperature for a first time duration;
(b2) after (b1), ceasing heating such that a temperature of the solid-state precursors decreases over a second time duration; and
(b3) repeating (b1) and (b2).

31-35. (canceled)

36. The method of claim 1, wherein the vapor solidifies on said deposition substrate surface to form individual multielement nanoparticles, each nanoparticle comprising at least Mo, Mn, Fe, Co, and Ni.

37. The method of claim 1, wherein the vapor solidifies on said deposition substrate surface to form individual MoMnFeCoNiOₓ high-entropy-oxide hexagonal nanodisks.

38. The method of claim 1, wherein the vapor solidifies on said deposition substrate surface to form individual FeCoNiS or CuCoNiFeMnS nanoparticles.

39. The method of claim 1, wherein the vapor solidifies on said deposition substrate surface to form individual FeCoNiCuPd high-entropy-alloy polyhedral nanoparticles.

40. The method of claim 1, wherein the vapor solidifies on said deposition substrate surface to form a homogeneous ZrO₂ film.

41-42. (canceled)

43. The method of claim 1, further comprising, after (b):
providing a second batch of solid-state precursors to the confined heating volume; and
subjecting the second batch of solid-state precursors to the first temperature so as to convert at least some of the solid-state precursors into a vapor that exits the confined heating volume via the at least one window, the exiting vapor flowing around the baffle member into contact with the deposition substrate such that the vapor solidifies thereon.

44. The method of claim 43, wherein the providing the second batch comprises displacing the support member in a direction crossing the first direction so as to dispose the second batch within the confined heating volume.

45-48. (canceled)

49. A system comprising:
a support member constructed to hold one or more batches of solid-state precursors thereon;
a baffle member disposed over and spaced from the support member by a first distance along a first direction, the baffle and support members being constructed and arranged to define a confined heating volume with at least one exit window;
a deposition substrate disposed over and spaced from the baffle member by a second distance along the first direction; and
a controller comprising one or more processors and one or more computer readable storage media,
wherein the baffle member comprises a heating element, and
the one or more computer readable storage media store instructions that, when executed by the one or more processors, cause the controller to control the heating element to subject a batch of solid-state precursors within the confined heating volume to a first temperature greater than 2200 K, so as to convert at least some of the solid-state precursors into a vapor that exits the confined heating volume via the at least one exit window, flows around the baffle member into contact with a surface of the deposition substrate, and solidifies on said deposition substrate surface.

50. The system of claim 49, wherein the heating element is a Joule heating element.

51-52. (canceled)

53. A system comprising:
a support member constructed to hold one or more batches of solid-state precursors thereon;
a baffle member disposed over and spaced from the support member by a first distance along a first direction, the baffle and support members being constructed and arranged to define a confined heating volume with at least one exit window;
a deposition substrate disposed over and spaced from the baffle member by a second distance along the first direction;
a heating system; and
a controller operatively coupled to the heating system, the controller comprising one or more processors and one or more computer readable storage media storing instructions that, when executed by the one or more processors, cause the controller to control the heating system to subject a batch of solid-state precursors within the confined heating volume to a first temperature greater than 2200 K, so as to convert at least some of the solid-state precursors into a vapor that exits the confined heating volume via the at least one exit window, flows around the baffle member into contact with a surface of the deposition substrate, and solidifies on said deposition substrate surface.

54. The system of claim 53, wherein the heating system comprises a Joule heating element, a microwave heating source, a laser, an electron beam device, a spark discharge device, or any combination of the foregoing.

55-57. (canceled)

58. The system of claim 53, wherein the at least one exit window is defined by a vertical gap between the baffle member and the support member.

59-60. (canceled)

61. The system of claim 53, further comprising:
a cooling device thermally coupled to the deposition substrate,
wherein the controller is operatively coupled to the cooling device, and
the one or more computer readable storage media store additional instructions that, when executed by the one or more processors, cause the controller to control the cooling device to maintain a temperature of the deposition substrate surface below 1000 K.

62-66. (canceled)

67. The system of claim 53, wherein the one or more computer readable storage media store instructions that, when executed by the one or more processors, cause the controller to subject the batch of solid-state precursors to the first temperature by:
(a) subjecting the first batch of solid-state precursors to the first temperature for a first time duration;
(b) after (a), ceasing heating such that a temperature of the solid-state precursors decreases over a second time duration; and
(c) repeating (a) and (b).

68-70. (canceled)
